(19) United States
(12) Patent Application Publication
(10) Pub. No.: US 2004/0046168 A1
(43) Pub. Date: Mar. 11, 2004

(54) Porous metal oxide semiconductor spectrally sensitized with metal oxide

(75) Inventor: Hieronymus Andriessen, Beerse (BE)

Correspondence Address: LEYDIG VOIT & MAYER, LTD, TWO PRUDENTIAL PLAZA, SUITE 4900, 180 NORTH STETSON AVENUE, CHICAGO, IL, 60601-6780, US

(73) Assignee: AGFA-GEVAERT, Mortsel (BE)

(21) Appl. No.: 10/630,492

(22) Filed: Jul. 30, 2003

Related U.S. Application Data
(60) Provisional application No. 60/406,358, filed on Aug. 27, 2002.

(30) Foreign Application Priority Data
Aug. 13, 2002 (EP) 02102131.6

(51) Int. Cl. H01L 29/12

(52) U.S. Cl. 257/43

(57) ABSTRACT

A porous metal oxide semiconductor with a band gap of greater than 2.9 eV spectrally sensitized on its internal and external surface with one or more metal oxides with a band-gap of less than 2.9 eV or a mixture thereof; a process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating the nano-porous metal oxide oxide with a band-gap of greater than 2.9 eV to which the metal salt had been applied to pyrolyse or hydrolyse and subsequently pyrolyse the salt to the metal oxide with a band-gap of less than 2.9 eV; and a second process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which the water-soluble polymer is no longer present in the coating support.

This application claims the benefit of U.S. Provisional Application No. 60/406,358 filed Aug. 27, 2002, which is incorporated by reference. In addition, this application claims the benefit of European Application No. 02102131.6 filed Aug. 13, 2002, which is also incorporated by reference.

### FIELD OF THE INVENTION

The present invention relates to a porous titanium dioxide in-situ spectrally sensitized with metal oxide.

### BACKGROUND OF THE INVENTION

There are two basic types of photoelectrochemical photovoltaic cells. The first type is the regenerative cell which converts light to electrical power leaving no net chemical change behind. Photons of energy exceeding that of the band gap generate electron-hole pairs, which are separated by the electrical field present in the space-charge layer. The negative charge carriers move through the bulk of the semiconductor to the current collector and the external circuit. The positive holes (h⁺) are driven to the surface where they are scavenged by the reduced form of the redox relay molecular (R), oxidizing it: h⁺+R→O, the oxidized form. O is reduced back to R by the electrons that re-enter the cell from the external circuit. In the second type, photosynthetic cells, operate on a similar principle except that there are two redox systems: one reacting with the holes at the surface of the semiconductor electrode and the second reacting with the electrons entering the counter-electrode. In such cells water is typically oxidized to oxygen at the semiconductor photoanode and reduced to hydrogen at the cathode. Titanium dioxide has been the favoured semiconductor for these studies. Unfortunately because of its large band-gap (3 to 3.2 eV), TiO₂ absorbs only part of the solar emission and so has low conversion efficiencies. Graetzel reported in 2001 in Nature, volume 414, page 338, that numerous attempts to shift the spectral response of TiO₂ into the visible had so far failed.

Mesoscopic or nano-porous semiconductor materials, minutely structured materials with an enormous internal surface area, have been developed for the regenerative type of cell to improve the light capturing efficiency by increasing the area upon which the spectrally sensitizing species could adsorb. Arrays of nano-crystals of oxides such as TiO₂, ZnO, SnO₂ and Nb₂O₅ or chalcogenides such as CdSe are the preferred mesoscopic semiconductor materials and are interconnected to allow electrical conduction to take place. A wet type solar cell having a porous film of dye-sensitized titanium dioxide semiconductor particles as a work electrode was expected to surpass an amorphous silicon solar cell in conversion efficiency and cost. These fundamental techniques were disclosed in 1991 by Graetzel et al. in Nature, volume 353, pages 737-740 and in U.S. Pat. No. 4,927,721, U.S. Pat. No. 5,350,644 and JP-A 05-504023. Graetzel et al. reported solid-state dye-sensitized mesoporous TiO₂ solar cells with up to 33% photon to electron conversion efficiences.

U.S. Pat. No. 4,927,721 discloses a regenerative photo-electrochemical cell comprising a polycrystalline metal oxide semi-conductor having a surface with a roughness factor of more than 20; and a monomolecular chromophore layer on said surface of said semiconductor.

In 1995 Tennakone et al. in Semiconductor Sci. Technol., volume 10, page 1689 and O'Regan et al. in Chem. Mater., volume 7, page 1349 reported an all-solid-state solar cell consisting of a highly structured heterojunction between a p- and n-type semiconductor with a absorber in between in which the p-semiconductor is CuSCN or CuI, the n-semiconductor is nano-porous titanium dioxide and the absorber is an organic dye.

Furthermore, in 1998 K. Tennakone et al. reported in Journal Physics A: Applied Physics, volume 31, pages 2326-2330, a nanoporous n-TiO₂/˜23 nm selenium film/p-CuCNS photovoltaic cell which generated a photocurrent of ˜3.0 mA/cm², a photovoltage of ˜600 mV at 800 W/m² simulated sunlight and a maximum energy conversion efficiency of ˜0.13%.

In 1994 Hoyer et al. reported in Applied Physics, volume 66, page 349, that the inner surface of a porous titanium dioxide film could be homogeneously covered with isolated quantum dots and Vogel et al. reported in Journal of Physical Chemistry, volume 98, pages 3183-3188, the sensitization of various nanoporous wide-bandgap semiconductors, specifically TiO₂, Nb₂O₅, Ta₂O₅, SnO₂ and ZnO, with quantum-sized PbS, CdS, Ag₂S, Sb₂S₃ and Bi₂S₃ and the use of quantum dot-sensitized oxide semiconductors in liquid junction cells.

EP-A 1 176 646 discloses a solid state p-n heterojunction comprising an electron conductor and a hole conductor, characterized in that if further comprises a sensitizing semiconductor, said sensitizing being located at an interface between said electron conductor and said hole conductor; and its application in a solid state sensitized photovoltaic cell. In a preferred embodiment the sensitizing semiconductor is in the form of particles adsorbed at the surface of said electron conductor and in a further preferred embodiment the sensitizing semiconductor is in the form of quantum dots.

In 1977 Kung et al. in Journal of Applied Physics, volume 48, pages 2463 to 2469, reported the electrochemical properties of the semiconducting anodes of TiO₂, SrTiO₃, BaTiO₃, Fe₂O₃, CdO, CdFe₂O₄, WO₃, PbFe₁₂O₁₉, PbTi_{1.5}W_{0.5}O_{6.5}, Hg₂Ta₂O₇ and Hg₂Nb₂O₇ in photosynthetic photovoltaic cells regarding the photoassisted electrolysis of water.

In 1999 Shiyanovskaya et al. in Journal of the Electrochemical Society, volume 146, pages 243 to 249, analyzed the capability of porous tungsten trioxide films as a material for photocurrent generation. They compared the photogeneration properties of single-component WO₃ and TiO₂ films and bicomponent WO₃/TiO₂ films. The morphology, structure, fundamental absorption edge, flatband potential, vibration spectra, and photocurrent response of the amorphous WO₃ films and nanocrystlline TiO₂ films were measured. They found that in bicomponent WO₃/TiO₂ films, the porous films of the WO₃ with a high open surface energy can serve as substrates for nanocrystalline TiO₂ films to increase the efficiency of photocurrent generation at bandgap excitation.

In 1994 Martin et al. in Journal of Physical Chemistry, volume 98, pages 13695 to 13704, reported that vanadium-doped titanium dioxide prepared by sintering hydrolysed titanium(IV) tetraisopropoxide and vanadium(III) chloride at 200-400° C. resulted in surficial islands of V₂O₅ on the TiO₂. Vanadium doping of titanium dioxide was found to reduce the photo-oxidation rates of 4-chlorophenol.

In 1995 Taverner et al. in Physical Review B, volume 51, pages 6833 to 6837, reported a comparison of the energies of vanadium donor levels in doped SnO₂ and TiO₂ prepared by firing pellets of mixed SnO₂ or TiO₂ and V₂O₅ at 1200° C., whereupon vanadium is incorporated in SnO₂ and TiO₂ as V⁴⁺.

Wang et al. reported the photocatalytic activity of nanocrystalline titania-based materials in an internet publication (http://web.mit.edu/cmse/www/Ying99.pdf). The basic principle of semiconductor photocatalysis involves photon-generated electrons and holes that, upon migrating to the surface, serve as redox sources and react with adsorbed reactants. The effectiveness of selective dopants such as Fe³⁺ and Nb⁵⁺ and/or noble metal deposition in modifying the electronic structure of TiO₂ and thereby enhancing photoactivity was noted to have a strong dependency on the crystalline size of the TiO₂ particle with respect to photo-assisted oxidation of chloroform in the liquid phase and trichloroethylene in the gas phase.

JP 2001-261436 discloses a semiconductor characterized by being the semiconductor which consists of sintered compacts of the semiconductor material which is mainly concerned with titanium dioxide, and being porosity. JP 2001-261436 further discloses a solar cell comprising a substrate, a first electrode placed on the upper surface of the substrate, a semiconductor placed on the upper surface of the first electrode, and a second electrode placed on the upper surface of the semiconductor, wherein the semiconductor is porous and consists of a sintered body of a semiconductor material that contains, as its main component, titanium dioxide which consists essentially of titanium dioxide preferably having an anatase-type crystal structure; preferably, the semiconductor has 1-50% porosity and the light-receiving surface of the semiconductor has a 5 nm to 10 μm surface roughness value (Ra); and also preferably, the constituent semiconductor material of the semiconductor contains an inorganic sensitizer e.g. Cr, V, Ni, Fe, Mn, Cu, Zn and Nb oxides; a sintering aid e.g. MoO₃, Bi₂O₃, PdO, PbO, Sb₂O₃, TeO₂, Th₂O₃; and an organic substance, e.g. fats and oils, styrene resins, acrylic resins, polyolefins, ethylene vinyl acetate copolymer, polyamides, polyesters, polyethers, various waxes, paraffin, cellulose, starch and phthalic acid esters, for forming pores upon removal by heat treatment in a non-oxidizing atmosphere; and is sintered at a ≦900° C. sintering temperature. In the invention examples only chromium oxides are exemplified as inorganic sensitizers.

JP 2001-203375, JP 2001-172079, JP 2001-170496, JP 2001-126782 and JP 2001-126782 disclose a semiconductor with excellent photoelectric conversion efficiency consisting of sintered compacts of mesoscopic titanium dioxide containing an inorganic spectral sensitizer, such as chromium or vanadium oxides, with a titanium dioxide particle size of 2-2000 nm and a molar concentration of inorganic spectral sensitizer to titanium dioxide in the range of 8×10⁻⁶ to 2×10⁻⁴:1 being preferred, with a molar concentration range of 1.2×10⁻⁴ to 1.6×10⁻⁴ being particularly preferred. Furthermore, a process for spectrally sensitizing a mesoscopic semiconductor was disclosed in which the mesoscopic semiconductor, e.g. titanium dioxide, an inorganic sensitizer, e.g. chromium(III) oxide, a sintering aid, e.g. molybdenum(VI) oxide with a melting point of 795° C., and an organic substance for forming pores, e.g. ethylene-vinylacetate copolymer, are sintered together at a temperature ≦900° C. The disclosures of JP 2001-261436, JP 2001-203375, JP 2001-172079, JP 2001-170496, JP 2001-126782 and JP 2001-126782 indicate incorporation of the inorganic sensitizer into the anatase lattice of the titanium dioxide.

EP-A 1 164 603 discloses a photoelectric conversion device comprising: a conductive support; a photosensitive layer containing a semiconductor fine particle on which a dye is adsorbed; a charge transfer layer; and a counter electrode, wherein said dye is treated with a treatment solution composed of a quaternary salt and a solvent before or after said dyes is adsorbed on said semiconductor fine particle.

Spectral sensitization broad-band semiconductors such as titanium dioxide with inorganic spectral sensitizers is required together with lower temperature processes to realize such spectral sensitization.

### ASPECTS OF THE INVENTION

It is therefore an aspect of the present invention to provide thermally stable spectrally sensitized broad-band semiconductors.

It is a further aspect of the present invention to provide a process for preparing spectrally sensitized broad-band semiconductors.

It is also an aspect of the present invention to provide photovoltaic devices comprising spectrally sensitized broad-band semiconductors.

Further aspects and advantages of the invention will become apparent from the description hereinafter.

### SUMMARY OF THE INVENTION

It has been surprisingly found that porous metal oxide semiconductors with a band-gap of greater than 2.9 eV can be spectrally sensitized on their internal and external surfaces with metal oxides with a band-gap of less than 2.9 eV e.g. with vanadium(V) oxide, iron(III) oxide and copper(II) oxide using processes requiring sintering at temperatures of ca. 450° C.

Aspects of the present invention are also realized by a porous metal oxide semiconductor with a band gap of greater than 2.9 eV spectrally sensitized on its internal and external surface with one or more metal oxides with a band-gap of less than 2.9 eV or a mixture thereof.

Aspects of the present invention are also realized by a process for spectrally sensitizing a nano-porous metal oxide with a band-gap of greater than 2.9 eV comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating the nano-porous metal oxide with a band-gap of greater than 2.9 eV to which the metal salt had been applied to pyrolyse or hydrolyse and subsequently pyrolyse the salt to the metal oxide with a band-gap of less than 2.9 eV.

Aspects of the present invention are also realized by a process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which the water-soluble polymer is no longer present in the coating support.

Aspects of the present invention are also realized by a photovoltaic cell comprising a porous metal oxide semiconductor with a band gap of greater than 2.9 eV spectrally sensitized on its internal and external surface with one or more metal oxides with a band-gap of less than 2.9 eV or a mixture thereof.

Aspects of the present invention are also realized by a second photovoltaic cell comprising a porous metal oxide semiconductor prepared according to a process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating said nano-porous metal oxide oxide with a band-gap of greater than 2.9 eV to which said metal salt had been applied to pyrolyse or hydrolyse and subsequently pyrolyse said salt to said metal oxide with a band-gap of less than 2.9 eV.

Aspects of the present invention are also realized by a third photovoltaic cell comprising a porous metal oxide semiconductor prepared according to a process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which said water-soluble polymer is no longer present in said coating support.

Preferred embodiments are disclosed in the dependent claims.

### DETAILED DESCRIPTION OF THE INVENTION

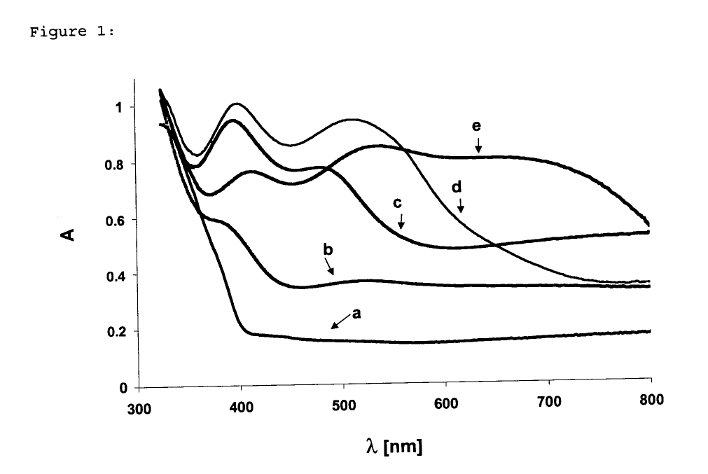

FIG. 1 represents the dependence of absorbance [A] upon wavelength [λ] in nm for: nano-porous TiO₂ layers without sensitization, curve a; sensitized with Ag₂O, curve b; sensitized with V₂O₅, curve c; sensitized with Fe₂O₃, curve d; and sensitized with CuO, curve e.

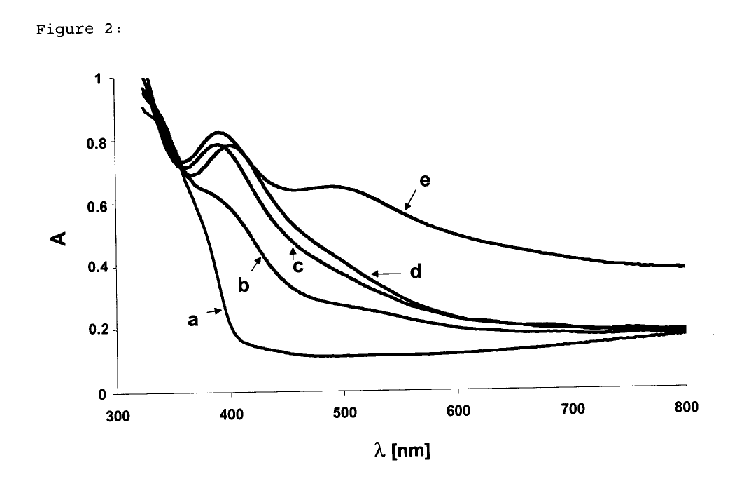

FIG. 2 represents the dependence of absorbance [A] upon wavelength [λ] in nm for: unsensitized TiO₂, curve a; a V₂O₅ to TiO₂ molar ratio of 0.024:1, curve b; a V₂O₅ to TiO₂ molar ratio of 0.048:1, curve c; a V₂O₅ to TiO₂ molar ratio of 0.073:1, curve d; and a V₂O₅ to TiO₂ molar ratio of 0.097:1, curve e.

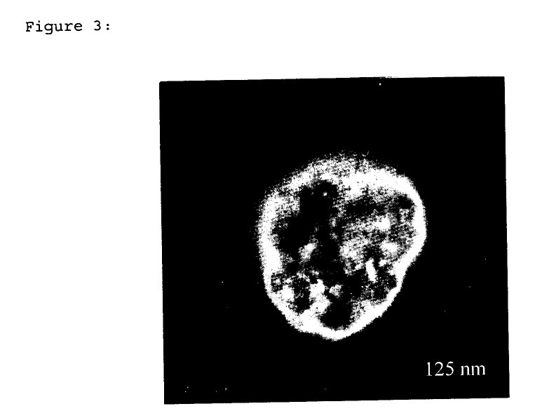

FIG. 3 is a dark field transmission electron micrograph of a porous TiO₂ layer with a V₂O₅ to TiO₂ molar ratio of 0.073:1. The 125 nm bar is approximately the length of the text in the micrograph.

### DEFINITIONS

The term porous metal oxide semiconductor means a metal oxide semiconductor with a pores accounting for at least 15% and not more than 90% of the volume thereof.

The term nano-porous metal oxide semiconductor means a metal oxide semiconductor having pores with a size of 100 nm or less and having an internal surface area of at least 20 m 2/g and not more than 300 m²/g.

The term “a mixture of two or more metal oxides” includes a simple mixture thereof, mixed crystals thereof and doping of a metal oxide by metal replacement.

The term internal surface means the surface of pores inside a porous material.

The term spectral sensitizer for the purposes of the present invention means a species having the ability to improve the response of the species being spectrally sensitized, i.e. spectrally sensitize it, to wavelengths of electromagnetic radiation e.g. light.

The term aqueous for the purposes of the present invention means containing at least 60% by volume of water, preferably at least 80% by volume of water, and optionally containing water-miscible organic solvents such as alcohols e.g. methanol, ethanol, 2-propanol, butanol, iso-amyl alcohol, octanol, cetyl alcohol etc.; glycols e.g. ethylene glycol; glycerine; N-methylpyrrolidone; methoxypropanol; and ketones e.g. 2-propanone and 2-butanone etc.

The term “support” means a “self-supporting material” so as to distinguish it from a “layer” which may be coated on a support, but which is itself not self-supporting. It also includes any treatment necessary for, or layer applied to aid, adhesion to the support.

The term continuous layer refers to a layer in a single plane covering the whole area of the support and not necessarily in direct contact with the support.

The term non-continuous layer refers to a layer in a single plane not covering the whole area of the support and not necessarily in direct contact with the support.

The term coating in used as a generic term including all means of applying a layer including all techniques for producing continuous layers, such as curtain coating, doctor-blade coating etc., and all techniques for producing non-continuous layers such as screen printing, ink jet printing, flexographic printing, and techniques for producing continuous layers

The abbreviation PEDOT represents poly(3,4-ethylenedioxy-thiophene).

The abbreviation PSS represents poly(styrene sulphonic acid) or poly(styrenesulphonate).

### Porous Metal Oxide Semiconductor

Aspects of the present invention are realized by a porous metal oxide semiconductor with a band gap of greater than 2.9 eV spectrally sensitized on its internal and external surface with one or more metal oxides with a band-gap of less than 2.9 eV or a mixture thereof.

According to a first embodiment of the porous metal oxide semiconductor with a band gap of greater than 2.9 eV, according to the present invention, the porous metal oxide semiconductor is nano-porous.

According to a second embodiment of the porous metal oxide semiconductor, according to the present invention, the porous metal oxide semiconductor with a band gap of greater than 2.9 eV is an n-type semiconductor.

According to a third embodiment of the porous metal oxide semiconductor with a band gap of greater than 2.9 eV, according to the present invention, the porous metal oxide semiconductor with a band gap of greater than 2.9 eV is selected from the group consisting of titanium oxides, tin oxides, niobium oxides, tantalum oxides tungsten oxides and zinc oxides.

According to a fourth embodiment of the porous metal oxide semiconductor, according to the present invention, the porous metal oxide semiconductor with a band gap of greater than 2.9 eV is titanium dioxide.

According to a fifth embodiment of the porous metal oxide semiconductor, according to the present invention, the porous metal oxide is exclusive of an organic or organometallic spectral sensitizer.

### Metal Oxides with a Band-Gap of Less than 2.9 eV

According to a sixth embodiment of the porous metal oxide, according to the present invention, the molar ratio of the one or more metal oxides with a band-gap of less than 2.9 eV or a mixture thereof to the porous metal oxide semiconductor is in the range of 0.001 to 1.

According to a seventh embodiment of the porous metal oxide, according to the present invention, the molar ratio of the one or more metal oxides with a band-gap of less than 2.9 eV or a mixture thereof to the porous metal oxide semiconductor is in the range of 0.01 to 0.2.

According to an eighth embodiment of the porous metal oxide, according to the present invention, the metal oxides with a band-gap of less than 2.9 eV are selected from the group consisting of: cadmium(II) oxide, palladium(I) oxide, platinum(II) oxide, nickel(II) oxide, manganese(III) oxide, chromium(III) oxide, vanadium(V) oxide, vanadium(III) oxide, iron(III) oxide, lead(II, III) oxide and copper(II) oxide.

According to a ninth embodiment of the porous metal oxide, according to the present invention, the metal oxides with a band-gap is of less than 2.9 eV are selected from the group consisting of: vanadium(V) oxide, iron(III) oxide and copper(II) oxide.

### Phosphoric Acid or Phosphate

According to a tenth embodiment of the porous metal oxide semiconductor, according to the present invention, the porous metal oxide semiconductor further contains a phosphoric acid or a phosphate.

According to an eleventh embodiment of the porous metal oxide semiconductor, according to the present invention, the porous metal oxide semiconductor further contains a phosphoric acid is selected from the group consisting of, orthophosphoric acid, phosphorous acid, hypophosphorous acid and polyphosphoric acids.

Polyphosphoric acids include diphosphoric acid, pyrophosphoric acid, triphosphoric acid, tetraphosphoric acid, metaphosphoric acid and “polyphosphoric acid”.

According to a twelfth embodiment of the porous metal oxide semiconductor, according to the present invention, the porous metal oxide semiconductor further contains a phosphate is selected from the group consisting of orthophosphates, phosphates, phosphites, hypophosphites and polyphosphates.

Polyphosphates are linear polyphosphates, cyclic polyphosphates or mixtures thereof. Linear polyphosphates contain 2 to 15 phosphorus atoms and include pyrophosphates, dipolyphosphates, tripolyphosphates and tetrapolyphosphates. Cyclic polyphosphates contain 3 to 8 phosphorus atoms and include trimetaphosphates and tetrametaphosphates and metaphosphates.

Polyphosphoric acid may be prepared by heating H₃PO₄ with sufficient P₄O₁₀ (phosphoric anhydride) or by heating H₃PO₄ to remove water. A P₄O₁₀/H₂O mixture containing 72.74% P₄O₁₀ corresponds to pure H₃PO₄, but the usual commercial grades of the acid contain more water. As the P₄O₁₀ content H₄P₂O₇, pyrophosphoric acid, forms along with P₃ through P₈ polyphosphoric acids. Triphosphoric acid appears at 71.7% P₂O₅ (H₅P₃O₁₀) and tetraphosphoric acid (H₆P₄O₁₃) at about 75.5% P₂O₅. Such linear polyphosphoric acids have 2 to 15 phosphorus atoms, which each bear a strongly acidic OH group. In addition, the two terminal P atoms are each bonded to a weakly acidic OH group. Cyclic polyphosphoric acids or metaphosphoric acids, HₙPₙO₃ₙ, which are formed from low-molecular polyphosphoric acids by ring closure, have a comparatively small number of ring atoms (n=3-8). Each atom in the ring is bound to one strongly acidic OH group. High linear and cyclic polyphosphoric acids are present only at acid concentrations above 82% P₂O₅. Commercial phosphoric acid has a 82 to 85% by weight P₂O₅ content. It consists of about 55% tripolyphosphoric acid, the remainder being H₃PO₄ and other polyphosphoric acids.

A polyphosphoric acid suitable for use according to the present invention is a 84% (as P₂O₅) polyphosphoric acid supplied by ACROS (Cat. No. 19695-0025).

### Process for Spectral Sensitization of a Porous Metal Oxide Semiconductor with Metal Oxide with a Band-Gap of Less than 2.9 eV

Aspects of the present invention are also realized by a process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating the nano-porous metal oxide with a band-gap of greater than 2.9 eV to which the metal salt had been applied to pyrolyse or hydrolyse and subsequently pyrolyse the salt to the metal oxide oxide with a band-gap of less than 2.9 eV.

Aspects of the present invention are also realized by a second process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which the water-soluble polymer is no longer present in the coating support.

Suitable metal compounds include organometallic compounds such as alkoxy-derivatives. Suitable metal salts include halides, hydroxides, citrates, tartrates, oxalates, acetates, carbonates, nitrates and salts with EDTA. Metal salts are used as aqueous solutions and metal compounds as solutions containing organic solvents.

According to a first embodiment of the processes, according to the present invention, the aqueous solution further contains a phosphoric acid or a phosphate.

Phosphoric acid or phosphate can, for example, be present in the metal salt solutions in which a porous metal oxide semiconductor, according to the present invention, such as nano-porous titanium dioxide, is dipped. The phosphoric acid or phosphate does not decompose during heating process, but can be removed after completion of the heating process using deionized water, whereupon an increase in the porosity of the porous mesoscopic titanium dioxide is realized and hence a higher degree of penetration by the electrolyte in liquid cells and higher short circuit currents.

Alternatively a phosphoric acid or a phosphate is present during the heating of the layer containing the salts, which, upon heating in the presence of the water-soluble polymer, are converted into a porous metal oxide semiconductor and a metal oxide with a band-gap of less than 2.9 eV and can be washed out with deionized water after heating thereby also increasing the porosity of the resulting porous metal oxide semiconductor.

According to a second embodiment of the processes, according to the present invention, the aqueous solution contains one or more further metal compounds or salts that pyrolyse or hydrolyse and subsequently pyrolyse to a metal oxides with a band-gap of less than 2.9 eV.

### Water-Soluble Polymers

Aspects of the present invention are realized by a process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which the water-soluble polymer is no longer present in the coating support.

Suitable water-soluble polymers for use in the process, according to the present, include polyvinylpyrrolidone, poly(vinyl alcohol), poly(vinyl acetate), polyacrylic acid, polymethacrylic acid, proteinaceous polymers, such as gelatin, cellulose derivatives and carbohydrates such as starch and sugars.

### Support

Supports for use according to the present invention include polymeric films, silicon, ceramics, oxides, glass, polymeric film reinforced glass, glass/plastic laminates, metal/plastic laminates, paper and laminated paper, optionally treated, provided with a subbing layer or other adhesion promoting means to aid adhesion to adjacent layers. Suitable polymeric films are poly(ethylene terephthalate), poly(ethylene naphthalate), polystyrene, polyethersulphone, polycarbonate, polyacrylate, polyamide, polyimides, cellulosetriacetate, polyolefins and poly(vinylchloride), optionally treated by corona discharge or glow discharge or provided with a subbing layer.

### Photovoltaic Devices

Aspects of the present invention are also realized by a photovoltaic cell comprising a porous metal oxide semiconductor with a band gap of greater than 2.9 eV spectrally sensitized on its internal and external surface with one or more metal oxides with a band-gap of less than 2.9 eV or a mixture thereof.

Aspects of the present invention are also realized by a second photovoltaic cell comprising a porous metal oxide semiconductor prepared according to a process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating said nano-porous metal oxide oxide with a band-gap of greater than 2.9 eV to which said metal salt had been applied to pyrolyse or hydrolyse and subsequently pyrolyse said salt to said metal oxide with a band-gap of less than 2.9 eV.

Aspects of the present invention are also realized by a third photovoltaic cell comprising a porous metal oxide semiconductor prepared according to a process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which said water-soluble polymer is no longer present in said coating support.

Photovoltaic devices incorporating the spectrally sensitized nano-porous metal oxide, according to the present invention, can be of two types: the regenerative type which converts light into electrical power leaving no net chemical change behind in which current-carrying electrons are transported to the anode and the external circuit and the holes are transported to the cathode where they are oxidized by the electrons from the external circuit and the photosynthetic type in which there are two redox systems one reacting with the holes at the surface of the semiconductor electrode and one reacting with the electrons entering the counter-electrode, for example, water is oxidized to oxygen at the semiconductor photoanode and reduced to hydrogen at the cathode. In the case of the regenerative type of photovoltaic cell, as exemplified by the Graetzel cell, the hole transporting medium may be a liquid electrolyte supporting a redox reaction, a gel electrolyte supporting a redox reaction, an organic hole transporting material, which may be a low molecular weight material such as 2,2′,7,7′-tetrakis(N,N-di-p-methoxyphenyl-amine)9,9′-spirobifluorene (OMeTAD) or triphenylamine compounds or a polymer such as PPV-derivatives, poly(N-vinylcarbazole) etc., or inorganic semiconductors such as CuI, CuSCN etc. The charge transporting process can be ionic as in the case of a liquid electrolyte or gel electrolyte or electronic as in the case of organic or inorganic hole transporting materials.

Such regenerative photovoltaic devices can have a variety of internal structures in conformity with the end use. Conceivable forms are roughly divided into two types: structures which receive light from both sides and those which receive light from one side. An example of the former is a structure made up of a transparently conductive layer e.g. an ITO-layer or a PEDOT/PSS-containing layer and a transparent counter electrode electrically conductive layer e.g. an ITO-layer or a PEDOT/PSS-containing layer having interposed therebetween a photosensitive layer and a charge transporting layer. Such devices preferably have their sides sealed with a polymer, an adhesive or other means to prevent deterioration or volatilization of the inside substances. The external circuit connected to the electrically-conductive substrate and the counter electrode via the respective leads is well-known.

Alternatively the spectrally sensitized nano-porous metal oxide, according to the present invention, can be incorporated in hybrid photovoltaic compositions such as described in 1991 by Graetzel et al. in Nature, volume 353, pages 737-740, in 1998 by U. Bach et al. [see Nature, volume 395, pages 583-585 (1998)] and in 2002 by W. U. Huynh et al. [see Science, volume 295, pages 2425-2427 (2002)]. In all these cases, at least one of the components (light absorber, electron transporter or hole transporter) is inorganic (e.g. nano-TiO₂ as electron transporter, CdSe as light absorber and electron transporter) and at least one of the components is organic (e.g. triphenylamine as hole transporter or poly(3-hexylthiophene) as hole transporter).

### Industrial Application

Porous metal oxide semiconductors, according to the present invention, can be used in both regenerative and photosynthetic photovoltaic devices.

The invention is illustrated hereinafter by way of reference and invention photovoltaic devices. The percentages and ratios given in these examples are by weight unless otherwise indicated.

### EXAMPLE 1

### Preparation of Solutions Used in In-Situ Preparation of Nano-Oxide Particles

Solution 1:

A 1 M aqueous solution of silver nitrate was prepared by dissolving 16.99 g of silver nitrate in deionized water and making up to 100 mL with deionized water.

Solution 2:

A 1 M aqueous solution of vanadium(III) chloride was prepared by dissolving 15.73 g of vanadium(III) chloride in deionized water and making up to 100 mL with deionized water.

Solution 3:

A 1 M aqueous solution of iron(III) chloride was prepared by dissolving 16.22 g of iron(III) chloride in deionized water and making up to 100 mL with deionized water.

Solution 4:

A 1 M aqueous solution of copper(II) chloride was prepared by dissolving 13.45 g of copper(II) chloride in deionized water and making up to 100 mL with deionized water.

### Efficient Adsorption of Nano-Oxides on a Nano-Porous TiO₂ Layer

A glass substrate (FLACHGLAS AG) was ultrasonically cleaned in ethanol for 5 minutes and then dried. 5 g of P25, a nano-sized titanium dioxide with a mean particle size of 25 nm and a specific surface of 55 m²/g from DEGUSSA, was added to 15 mL of water and then 1 mL of Triton X-100 was added. The resulting titanium dioxide colloidal dispersion was cooled in ice and ultrasonically treated for 5 minutes.

The titanium dioxide dispersion was then doctor-blade coated on the glass substrate and the coated layer heated at 450° C. for 30 minutes. A dry layer thickness of 2 Am was obtained as verified by laserprofilometry (DEKTRAK™ profilometer), mechanically with a diamond-tipped probe (Perthometer) and interferometry.

After the sintering step, the titanium dioxide-coated glass plates were cooled to 150° C. by placing them on a hot plate at 150° C. for 10 minutes and then immediately dipped into the particular metal salt solution indicated in Table 1 for 1 minute. The metal salt contained in the Solution was thereby deposited on the internal surface of the porous titanium dioxide. Then, the titanium oxide with the metal salt was heated again to 450° C. for 1 hour. Under such reaction conditions silver nitrate will be decomposed to silver oxide and vanadium(III), iron(III) chloride and copper(II) chloride will be hydrolyzed to the corresponding hydroxides which will in their turn be decomposed to the corresponding oxides, which will probably be at least partially present as nano-particles in view of the 18 nm pore-size of the sintered titanium dioxide. After cooling, absorption measurements were performed with a Shimadzu UV-3101 PC spectrophotometer with an ISR-3100 integration sphere in reflection mode.

The resulting absorption spectra are shown in FIG. 1 as dependences of absorbance [A] upon wavelength [λ] in nm: curve a representing a nano-porous TiO₂ layer without sensitization, curve b representing a nano-porous TiO₂ layer sensitized with Ag₂O (Solution 1), curve c representing a nano-porous TiO₂ layer sensitized with V₂O₅ (Solution 2), curve d representing a nano-porous TiO₂ layer sensitized with Fe₂O₃ (Solution 3) and curve e representing a nano-porous TiO₂ layer sensitized with CuO (Solution 4).

It can be concluded from FIG. 1 that the presence of the metal oxide formed from the metal salts contained in Solutions 2, 3 and 4 gave rise to strong absorption of visible light in the sintered titanium dioxide layers. Martin et al. in Journal of Physical Chemistry, volume 98, pages 13695 to 13704, reported in 1994 that vanadium-doped titanium dioxide prepared by sintering hydrolysed titanium(IV) tetraisopropoxide and vanadium(III) chloride at 200-400° C. resulted in surficial islands of V₂O₅ on the TiO₂ and that V⁴⁺ ions are not incorporated in the TiO₂ lattice.

Comparison of the absorption spectrum of curve c in FIG. 1 with the absorption spectra for the different TiO₂/V₂O₅ layers indicates that the V₂O₅ is deposited in the nano-porous mesoscopic titanium dioxide layer at a V₂O₅ to TiO₂ molar ratio similar to that of curve e of FIG. 2 i.e. 0.097:1.

### EXAMPLE 2

### Evaluation in Liquid Photovoltaic Devices

Photovoltaic devices 1 to 5 were prepared by the following procedure:

Preparation of the Front Electrode

A glass plate (2×7 cm²) coated with conductive SnO₂:F (Pilkington TEC15/3) with a surface conductivity of ca 15 Ohm/square was ultrasonically cleaned in isopropanol for 5 minutes and then dried.

The electrode was taped off at the borders and was doctor blade-coated in the middle (0.7×4.5 cm²) with the P25 titanium dioxide colloidal dispersion described in EXAMPLE 1 to give layer thicknesses after sintering of 2.0 μm.

The front electrodes 2, 3 and 4 for Devices 2, 3 and 4 respectively were prepared analogously to the corresponding titanium dioxide layers described in EXAMPLE 1. In the preparation of the front electrode 1 for Device 1 the same procedure was used as with the front electrodes 2, 3 an 4 except that deionized water was used instead of the Solution prior to the second sintering.

The front electrodes thereby produced were immediately used in assembling the cell.

Cell Assembly

The back electrode (consisting of SnO₂:F glass (Pilkington TEC15/3) evaporated with platinum to catalyse the reduction of the electrolyte) was sealed together with the front electrode with inbetween two pre-patterned layers of Surlyn® (DuPont) (2×7 cm² where in the middle 1×6 cm had been removed). This was performed at a temperature just above 100° C. on a hotplate. As soon as the sealing was completed, the cell was cooled to 25° C. and electrolyte was added through holes in the counter electrode. The electrolyte used was a solution of 0.5 M LiI, 0.05 M 12 and 0.4 M t-butylpyridine in acetonitrile and was injected into the cell during cell assembly. The holes were then sealed with Surlyn® and a thin piece of glass. Conductive tape was attached on both long sides of the cell to collect the electricity during measurement. Measurements were performed immediately after the cell assembly.

Device Characterisation

The thereby prepared photovoltaic cells were irradiated with a Xenon Arc Discharge lamp with a power of 100 mW/cm². The current generated was recorded with a Keithley electrometer (Type 2420). The open circuit voltage (V_{oc}), short circuit current density (I_{sc}) and Fill Factor (FF) of the photocell as calculated from the quality of generated current are given in Table 1.

TABLE 1

| | Front | | | V_{OC} | |
|---|---|---|---|---|---|
| Device nr | electrode | Spectral sensitizer | I_{SC} (mA/cm²) | (V) | FF |
| 1 (comp) | 1 | None | <0.001 | — | — |
| 2 (inv) | 2 | V₂O₅ | 0.003 | 0.045 | 0.31 |
| 3 (inv) | 3 | Fe₂O₃ | 0.02 | 0.150 | 0.30 |
| 4 (inv) | 4 | CuO | 0.03 | 0.155 | 0.34 |

It can be concluded from Table 2, that spectral sensitization of mesoscopic titanium dioxide in liquid photovoltaic cells can be carried out with nano-particles of low band-gap transition metal oxides. The spectral sensitization with iron(III) and copper(II) oxides appeared to be much stronger than that with vanadium(V) oxide, which was at least partly due to the substantially lower absorption of the vanadium(III) oxide-sensitized mesoscopic titanium dioxide layer.

### EXAMPLE 3

### Coprecipitation of Titanium Dioxide with Vanadium Oxide

The following solutions were prepared by mixing together the ingredients given for the particular solution in Table 4 at 25° C.

TABLE 4

| | aqueous solution of TiOCl₂ | | | | V₂O₅ to |
|---|---|---|---|---|---|
| Solu- | prepared by mixing 0.7 | | | | TiO₂ molar |
| tion | moles of TiCl₄/L of water | Ethanol | PVP* | VCl₃ | ratio after |
| nr. | [mL] | [mL] | [g] | [g] | sintering |
| 5 | 58 | 45 | 1 | — | 0:1 |
| 6 | 58 | 45 | 1 | 0.31 | 0.024:1 |
| 7 | 58 | 45 | 1 | 0.62 | 0.048:1 |
| 8 | 58 | 45 | 1 | 0.93 | 0.073:1 |
| 9 | 58 | 45 | 1 | 1.24 | 0.097:1 |

*PVP = polyvinylpyrrolidone

These solutions were refluxed for one hour at 100° C. during which the corresponding nano-Tiₓ(V_{y})O_{z} dispersions were obtained. These dispersions were then coated on glass and heated at 450° C. for 30 minutes resulting in layer thicknesses of about 2 μm.

Martin et al. in Journal of Physical Chemistry, volume 98, pages 13695 to 13704, reported in 1994 that vanadium-doped titanium dioxide prepared by sintering hydrolysed titanium(IV) tetraisopropoxide and vanadium(III) chloride at 200-400° C. resulted in surficial islands of V₂O₅ on the TiO₂ and that V⁴⁺ ions are not incorporated in the TiO₂ lattice. The layers therefore consist of TiO₂ with surficial islands of V₂O₅. The absorption spectra of the resulting layers of TiO₂ with surficial islands of V₂O₅ for different molar ratios of V₂O₅ to TiO₂ are shown in FIG. 2 in which curve a represents the dependence of absorbance upon wavelength for unsensitized TiO₂, curve b represents the dependence of absorbance upon wavelength for a V₂O₅ to TiO₂ molar ratio of 0.024:1, curve c represents the dependence of absorbance upon wavelength for a V₂O₅ to TiO₂ molar ratio of 0.048:1, curve d represents the dependence of absorbance upon wavelength for a V₂O₅ to TiO₂ molar ratio of 0.073:1, and curve e represents the dependence of absorbance upon wavelength for a V₂O₅ to TiO₂ molar ratio of 0.097:1.

It can be concluded from FIG. 2 that the absorption of visible light increased with increasing V₂O₅ to TiO₂ molar ratio in the sintered porous titanium dioxide layers.

FIG. 3 is a dark field transmission electron micrograph for a V₂O₅ to TiO₂ molar ratio of 0.073:1. The 125 nm bar is not visible, but is approximately as long as the text in the micrograph. The particles formed appear not to be nano-particles, although could be agglomerates of nano-particles. The edge of the particle appears to be enriched with vanadium oxide, which confirms the findings of Martin et al. mentioned above.

The present invention may include any feature or combination of features disclosed herein either implicitly or explicitly or any generalisation thereof irrespective of whether it relates to the presently claimed invention. In view of the foregoing description it will be evident to a person skilled in the art that various modifications may be made within the scope of the invention.

Having described in detail preferred embodiments of the current invention, it will now be apparent to those skilled in the art that numerous modifications can be made therein without departing from the scope of the invention as defined in the following claims.

All references, including publications, patent applications, and patents, cited herein are hereby incorporated by reference to the same extent as if each reference were individually and specifically indicated to be incorporated by reference and were set forth in its entirety herein.

The use of the terms “a” and “an” and “the” and similar referents in the context of describing the invention (especially in the context of the following claims) are to be construed to cover both the singular and the plural, unless otherwise indicated herein or clearly contradicted by context. Recitation of ranges of values herein are merely intended to serve as a shorthand method of referring individually to each separate value falling within the range, unless otherwise indicated herein, and each separate value is incorporated into the specification as if it were individually recited herein. All methods described herein can be performed in any suitable order unless otherwise indicated herein or otherwise clearly contradicted by context. The use of any and all examples, or exemplary language (e.g., “such as”) provided herein, is intended merely to better illuminate the invention and does not pose a limitation on the scope of the invention unless otherwise claimed. No language in the specification should be construed as indicating any non-claimed element as essential to the practice of the invention.

Preferred embodiments of this invention are described herein, including the best mode known to the inventors for carrying out the invention. Of course, variations of those preferred embodiments will become apparent to those of ordinary skill in the art upon reading the foregoing description. The inventors expect skilled artisans to employ such variations as appropriate, and the inventors intend for the invention to be practiced otherwise than as specifically described herein. Accordingly, this invention includes all modifications and equivalents of the subject matter recited in the claims appended hereto as permitted by applicable law. Moreover, any combination of the above-described elements in all possible variations thereof is encompassed by the invention unless otherwise indicated herein or otherwise clearly contradicted by context.

I claim:

1. A porous metal oxide semiconductor with a band gap of greater than 2.9 eV spectrally sensitized on its internal and external surface with one or more metal oxides with a band-gap of less than 2.9 eV or a mixture thereof.

2. Porous metal oxide semiconductor according to claim 1, wherein said porous metal oxide semiconductor with a band gap of greater than 2.9 eV is an n-type semiconductor.

3. Porous metal oxide semiconductor according to claim 1, wherein said metal oxides with a band-gap of less than 2.9 eV are selected from the group consisting of: vanadium(V) oxide, iron(III) oxide and copper(II) oxide.

4. Porous metal oxide semiconductor according to claim 1, wherein the molar ratio of said one or more metal oxides with a band-gap of less than 2.9 eV or a mixture thereof to said porous metal oxide semiconductor is in the range of 0.2 to 0.001 to 1.

5. Porous metal oxide semiconductor according to any of the preceding claims, wherein said porous metal oxide semiconductor further contains a phosphoric acid or a phosphate.

6. Porous metal oxide semiconductor according to claim 1, wherein said porous metal oxide semiconductor is nano-porous.

7. Porous metal oxide semiconductor according to claim 6, wherein said nano-porous metal oxide semiconductor with a band gap of greater than 2.9 eV is selected from the group consisting of titanium oxides, tin oxides, niobium oxides, tantalum oxides, tungsten oxides and zinc oxides

8. Porous metal oxide semiconductor according to claim 6, wherein said nano-porous metal oxide semiconductor with a band gap of greater than 2.9 eV is titanium dioxide.

9. A process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating said nano-porous metal oxide oxide with a band-gap of greater than 2.9 eV to which said metal salt had been applied to pyrolyse or hydrolyse and subsequently pyrolyse said salt to said metal oxide with a band-gap of less than 2.9 eV.

10. Process according to claim 9, wherein said aqueous solution further contains a phosphoric acid or a phosphate.

11. Process according to claim 9, wherein said aqueous solution contains one or more further metal compounds or salts that pyrolyse or hydrolyse and subsequently pyrolyse to metal oxides with a band-gap of less than 2.9 eV.

12. A second process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which said water-soluble polymer is no longer present in said coating support.

13. Second process according to claim 12, wherein said aqueous solution further contains a phosphoric acid or a phosphate.

14. Second process according to any of claim 12, wherein said aqueous solution contains one or more further metal compounds or salts that pyrolyse or hydrolyse and subsequently pyrolyse to metal oxides with a band-gap of less than 2.9 eV.

15. A photovoltaic cell comprising a porous metal oxide semiconductor with a band gap of greater than 2.9 eV spectrally sensitized on its internal and external surface with one or more metal oxides with a band-gap of less than 2.9 eV or a mixture thereof.

16. Photovoltaic cell according to claim 16, wherein said porous metal oxide semiconductor with a band gap of greater than 2.9 eV is an n-type semiconductor.

17. Photovoltaic cell according to claim 16, wherein said metal oxides with a band-gap of less than 2.9 eV are selected from the group consisting of: vanadium(V) oxide, iron(III) oxide and copper(II) oxide.

18. Photovoltaic cell according to claim 16, wherein the molar ratio of said one or more metal oxides with a band-gap of less than 2.9 eV or a mixture thereof to said porous metal oxide semiconductor is in the range of 0.2 to 0.001 to 1.

19. Photovoltaic cell according to claim 16, wherein said porous metal oxide semiconductor further contains a phosphoric acid or a phosphate.

20. Photovoltaic cell according to claim 16, wherein said porous metal oxide semiconductor is nano-porous.

21. Photovoltaic cell according to claim 20, wherein said nano-porous metal oxide semiconductor with a band gap of greater than 2.9 eV is selected from the group consisting of titanium oxides, tin oxides, niobium oxides, tantalum oxides, tungsten oxides and zinc oxides

22. Photovoltaic cell according to claim 20, wherein said nano-porous metal oxide semiconductor with a band gap of greater than 2.9 eV is titanium dioxide.

23. A second photovoltaic cell comprising a porous metal oxide semiconductor prepared according to a process for spectrally sensitizing a nano-porous metal oxide with a band-gap of greater than 2.9 eV on its internal and external surface comprising the steps of: providing a nano-porous metal oxide with a band gap of greater than 2.9 eV, applying a solution of a metal compound or salt which upon pyrolysis or upon hydrolysis and subsequent pyrolysis yields a metal oxide with a band-gap of less than 2.9 eV and heating said nano-porous metal oxide oxide with a band-gap of greater than 2.9 eV to which said metal salt had been applied to pyrolyse or hydrolyse and subsequently pyrolyse said salt to said metal oxide with a band-gap of less than 2.9 eV.

24. Second photovoltaic cell according to claim 23, wherein said aqueous solution further contains a phosphoric acid or a phosphate.

25. Second photovoltaic cell according to claim 23, wherein said aqueous solution contains one or more further metal compounds or salts that pyrolyse or hydrolyse and subsequently pyrolyse to metal oxides with a band-gap of less than 2.9 eV.

26. A third photovoltaic cell comprising a porous metal oxide semiconductor prepared according to a process for spectrally sensitizing a nano-porous metal oxide with a band-gap of greater than 2.9 eV on its internal and external surface comprising the steps of: (i) preparing a solution containing a metal compound or salt that pyrolyses or hydrolyses and subsequently pyrolyses to a metal oxide semiconductor with a band-gap of greater than 2.9 eV and a metal compound or salt that pyrolyses or hydrolyses and subsequently pyrolyses to a metal oxide with a band-gap of less than 2.9 eV, (ii) adding a water-soluble polymer to the solution prepared in step (i), (iii) coating the solution prepared in step (ii) on a support, and (iv) heating the coated support prepared in step (iii) to a temperature at which said water-soluble polymer is no longer present in said coating support.

27. Third photovoltaic cell according to claim 26, wherein said aqueous solution further contains a phosphoric acid or a phosphate.

28. Third photovoltaic cell according to claim 26, wherein said aqueous solution contains one or more further metal compounds or salts that pyrolyse or hydrolyse and subsequently pyrolyse to metal oxides with a band-gap of less than 2.9 eV.
